(19) United States
(12) Patent Application Publication
(10) Pub. No.: US 2003/0214040 A1
(43) Pub. Date: Nov. 20, 2003

(54) Semiconductor device and method of manufacturing the same

(75) Inventors: Takashi Yamashita, Tokyo (JP); Noriaki Fujiki, Tokyo (JP); Shoichi Fukui, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/288,998

(22) Filed: Nov. 7, 2002

(30) Foreign Application Priority Data
May 14, 2002 (JP) 2002-138396

(51) Int. Cl. H01L 23/48

(52) U.S. Cl. 257/758

(57) ABSTRACT

It is an object to enhance an adhesion strength of a bonding pad in a semiconductor device having a fluorine doped silicon oxide film as an interlayer insulating film. A second interlayer insulating film (4) provided with a bonding pad (6) on an upper surface has a three-layered structure including an F doped silicon oxide film (4a), a TEOS based silicon oxide film (4b) and an SiH₄ based silicon oxide film (4c). A dummy pattern (10) having an equal size to that of the bonding pad (6) is provided in a region right under the bonding pad (6), and the F doped silicon oxide film (4a) and the SiH₄ based silicon oxide film (4c) are in contact with each other in a region right on the dummy pattern (10). More specifically, an interface of the TEOS based silicon oxide film (4b) and the SiH₄ based silicon oxide film (4c) is hardly present in a region right under the bonding pad (6). Consequently, pile-up of fluorine is hardly generated in the region right under the bonding pad (6) so that an adhesion strength of the bonding pad (6) can be enhanced.

### BACKGROUND OF THE INVENTION

1. Field of the Invention

The present invention relates to a semiconductor device having a multilayered wiring structure.

2. Description of the Background Art

With an increase in integration and function of a semiconductor device, a wiring structure has become finer and been multi-layered to an increased degree. Accordingly, importance for reducing a distance between wirings in a multilayered wiring structure has been gained increasingly. However, when the distance between wirings is reduced, an electrostatic capacitance (a parasitic capacitance) between the wirings is increased. The increase in the capacitance greatly impedes a reduction in power consumption and an increase in a speed of the semiconductor device. In order to solve the problem, therefore, it is necessary to reduce the electrostatic capacitance between the wirings.

For example, referring to a design rule of a quarter micron or less, a material having a low dielectric constant is used for an interlayer insulating film in a semiconductor device requiring a high-speed operation. Consequently, the dielectric constant of the interlayer insulating film is decreased so that a parasitic capacitance between wirings can be reduced. Examples of the material having a low dielectric constant include a silicon oxide film containing a silicon (Si)—fluorine (F) bond (a fluorine doped silicon oxide film which will be hereinafter referred to as an “F doped silicon oxide film”) which is obtained by adding a gas containing fluorine when forming a silicon oxide film by plasma CVD (Chemical Vapor Deposition) or high density plasma CVD. In general, when the number of Si—F bonds in the F doped silicon oxide film is increased, a dielectric constant thereof is reduced.

FIG. 12 is a sectional view showing a structure of a conventional semiconductor device using the F doped silicon oxide film as an interlayer insulating film. As shown in FIG. 12, a first interlayer insulating film 2 comprising a silicon oxide film which contains little fluorine is formed on a silicon substrate 1 and a first aluminum (Al) wiring 3 is provided thereon in the semiconductor device. A second interlayer insulating film 4 having a three-layered structure including an F doped silicon oxide film 4a, a TEOS based silicon oxide film 4b and an SiH₄ based silicon oxide film 4c is formed to cover the first Al wiring 3. Furthermore, a second Al wiring 5 and a bonding pad 6 are provided on the second interlayer insulating film 4. The second Al wiring 5 and the first Al wiring 3 are electrically connected to each other through a contact plug, which is not shown. Moreover, a passivation film 7 formed by a silicon nitride film in which an upper part of the bonding pad 6 is opened is provided on the second Al wiring 5 and the bonding pad 6.

Moreover, FIGS. 13 to 15 are views for explaining a process for manufacturing the conventional semiconductor device illustrated in FIG. 12. With reference to these drawings, description will be given to the process for manufacturing the conventional semiconductor device. First of all, the first interlayer insulating film 2 formed by a silicon oxide film is provided on the silicon substrate 1, and the first Al wiring 3 is formed thereon. Such a forming method is executed by combining a CVD method, an etch back method, a CMP (Chemical Mechanical Polishing) method and the like, for example. The silicon oxide film constituting the first interlayer insulating film 2 is formed without an addition of fluorine. Then, the F doped silicon oxide film 4a is formed on the first interlayer insulating film 2 and the first Al wiring 3 to cover the first Al wiring 3 (FIG. 13). The F doped silicon oxide film 4a is formed by a high density plasma CVD method with an addition of an C₂F₆ gas to an SiH₄ gas and an O₂ gas, for example. At this time, a thickness of the F doped silicon oxide film 4a is almost equal to that of the first Al wiring 3.

When the F doped silicon oxide film 4a is to be formed by the high density plasma CVD method, deposition of the F doped silicon oxide film 4a and sputter etching of an oxide film by fluorine dissociated in a vapor are carried out at the same time. Therefore, a film forming speed is reduced and a step coverage property is enhanced. Moreover, a shoulder portion of the oxide film thus formed is etched in a portion provided with a lower step by the influence of the etching with the fluorine. Accordingly, the F doped silicon oxide film 4a becomes triangular as shown in FIG. 13 over the first Al wiring 3.

It is necessary to flatten an upper surface of the interlayer insulating film 4 in order to form the second Al wiring 5 above the first Al wiring 3 as shown in FIG. 12. The CMP method can be proposed as a flattening method. However, it is hard to flatten the triangular F doped silicon oxide film 4a shown in FIG. 13 with high precision, and a variation is apt to be caused in a film thickness. In general, if a film to be flattened is previously formed thickly and a margin is provided for the film thickness, the precision in flattening can be increased comparatively easily. However, the F doped silicon oxide film 4a is formed at a lower speed than an ordinary silicon oxide film to which the fluorine is not added, and a cost of formation is increased. In respect of a manufacturing efficiency and a manufacturing cost, therefore, it is not preferable that the thickness of the F doped silicon oxide film 4a should be increased unnecessarily.

For this reason, the TEOS based silicon oxide film 4b is formed on the F doped silicon oxide film 4a by a plasma CVD method using TEOS (tetraethylorthosilicate; Si(OCH₂CH₃)₄) and an O₂ gas as reaction gases, thereby increasing a thickness of the film to be flattened (FIG. 14). The TEOS based silicon oxide film 4b formed by the plasma CVD method reflects the lower step comparatively faithfully and is formed conformally. Consequently, the TEOS based silicon oxide film 4b provided above the first Al wiring 3 also becomes triangular.

Then, a flattening treatment is carried out over the F doped silicon oxide film 4a and the SiH₄ based silicon oxide film 4c by the CMP method. Since the margin is provided for the thickness of the film to be scraped as described above, it is possible to carry out the flattening with high precision. Subsequently, a heat treatment is carried out at approximately 400° C. in order to improve quality of the F doped silicon oxide film 4a and the TEOS based silicon oxide film 4b which are subjected to the CMP treatment. At this time, the fluorine having a small bonding strength in the F doped silicon oxide film 4a is diffused into the TEOS based silicon oxide film 4b.

Thereafter, the SiH₄ based silicon oxide film 4c is formed on the F doped silicon oxide film 4a and the TEOS based silicon oxide film 4b which are flattened (FIG. 15). The SiH₄ based silicon oxide film 4c is formed by the plasma CVD method using SiH₄ and O₂ as reaction gases. As a result, the second interlayer insulating film 4 has a three-layered structure including the F doped silicon oxide film 4a, the TEOS based silicon oxide film 4b and the SiH₄ based silicon oxide film 4c as shown in FIG. 15. The reason why the SiH₄ based silicon oxide film 4c is provided will be described below.

Subsequently, a via hole for connecting the first Al wiring 3 to the second Al wiring 5 is formed on the second interlayer insulating film 4 by photolithography, dry etching and the like, which is not shown. By a combination of sputtering, the CVD method, the etch back method, the CMP method and the like, a tungsten plug is buried in the via hole to form a contact.

Then, the second Al wiring 5 and the bonding pad 6 are formed on the second interlayer insulating film 4. At this time, the second Al wiring 5 is formed to cover the contact connected to the first Al wiring 3 which is formed previously. Thereafter, a silicon nitride film to be the passivation film 7 is formed by the plasma CVD method, for example, and the upper part of the bonding pad 6 is opened so that the semiconductor device shown in FIG. 12 is formed.

As is apparent from FIG. 12, the bonding pad 6 is formed on the SiH₄ based silicon oxide film 4c without a contact with the TEOS based silicon oxide film 4b. In the case in which the bonding pad 6 is directly formed on the TEOS based silicon oxide film 4b into which the fluorine is diffused, the fluorine in the TEOS based silicon oxide film 4b is diffused into an interface with the bonding pad 6 when a heat treatment such as annealing for stabilizing a characteristic of the semiconductor device is carried out in a subsequent manufacturing process. Thereafter, a compound (for example, titanium fluoride) of a barrier metal (for example, titanium) on a surface of the bonding pad 6 and the fluorine is formed on the interface. As a result, an adhesion strength of the bonding pad 6 and the second interlayer insulating film 4 is deteriorated. In general, a lead wire is soldered to the bonding pad 6 and external force such as heat, pressure or oscillation is applied through the lead wire. Therefore, when the adhesion strength of the bonding pad 6 is small, the bonding pad 6 is peeled.

On the other hand, the SiH₄ based silicon oxide film 4c is dense and has such a feature that the fluorine is diffused therein with difficulty. For this reason, the bonding pad 6 is formed through the SiH₄ based silicon oxide film 4c without a direct contact with the TEOS based silicon oxide film 4b as shown in FIG. 12. Consequently, the fluorine does not reach the interface of the bonding pad 6 and the second interlayer insulating film 4. Accordingly, it is possible to prevent the adhesion strength from being reduced over the interface of the bonding pad 6 and the second interlayer insulating film 4.

In the SiH₄ based silicon oxide film 4c, a composition ratio of Si to O can be regulated by adjusting a flow ratio of the SiH₄ gas to the O₂ gas, pressure, RF power and the like in the plasma CVD method. A film which is Si richer than a stoichiometric ratio and has a refractive index n=approximately 1.5 to 1.6 (λ=632.8 nm) is optimum for the SiH₄ based silicon oxide film 4c.

As described above, the SiH₄ based silicon oxide film 4c is present between the bonding pad 6 and the TEOS based silicon oxide film 4b so that the adhesion strength of the second interlayer insulating film 4 and the bonding pad 6 can be prevented from being reduced. The reason is that a barrier effect of the SiH₄ based silicon oxide film 4c against the fluorine is great. However, the following problem arises due to the barrier effect.

FIG. 16 is a view for explaining the problem of the conventional semiconductor device. For example, a temperature of approximately 400° C. is brought at a step of forming a tungsten film for providing a contact by the CVD method, a step of forming the second Al wiring 5 by sputtering and a step of forming the passivation film 7 by the plasma CVD method. Apparently, these steps are carried out after the formation of the SiH₄ based silicon oxide film 4c. In some cases, moreover, annealing is carried out at approximately 400° C. in order to stabilize a device characteristic after the formation of the semiconductor device. When such a heat treatment is carried out after the formation of the SiH₄ based silicon oxide film 4c, the diffusion of the fluorine from the F doped silicon oxide film 4a to the TEOS based silicon oxide film 4b further progresses. Since the TEOS based silicon oxide film 4b has little bonding for bonding to the fluorine, a capability for holding the fluorine diffused therein is poor.

Thus, when the fluorine is further diffused into the TEOS based silicon oxide film 4b by the heat treatment carried out after the formation of the SiH₄ based silicon oxide film 4c, a phenomenon in which the fluorine is accumulated in the interface of the TEOS based silicon oxide film 4b and the SiH₄ based silicon oxide film 4c, that is, pile-up is caused by the barrier effect of the SiH₄ based silicon oxide film 4c against the fluorine. As a result, an F layer 50 having a high concentration of fluorine is formed on the interface of the TEOS based silicon oxide film 4b and the SiH₄ based silicon oxide film 4c as shown in FIG. 16, and an adhesion strength in the same portion is thereby reduced.

More specifically, in the conventional semiconductor device, the adhesion strength between the second interlayer insulating film 4 and the bonding pad 6 can be enhanced by the presence of the SiH₄ based silicon oxide film 4c, while the adhesion strength between the TEOS based silicon oxide film 4b and the SiH₄ based silicon oxide film 4c in the second interlayer insulating film 4 is low. Accordingly, even if an adhesion is maintained between the bonding pad 6 and the SiH₄ based silicon oxide film 4c when external force is applied to the bonding pad 6 through a lead wire 9 fixed by a solder 8, peeling is caused between the TEOS based silicon oxide film 4b and the SiH₄ based silicon oxide film 4c (the F layer 50 portion having a high concentration of fluorine) in some cases. In other words, consequently, the adhesion strength of the bonding pad 6 is reduced. When the peeling of the bonding pad 6 is generated, a chip having no problem in a device characteristic also causes a reduction in a semiconductor device manufacturing yield and a deterioration in an operation reliability by a disconnection.

### SUMMARY OF THE INVENTION

It is an object of the present invention to provide a semiconductor device having a fluorine doped silicon oxide film as an interlayer insulating film which can enhance an adhesion strength of a bonding pad, and a method of manufacturing the semiconductor device.

A first aspect of the present invention is directed to a semiconductor device including an interlayer insulating film having a multilayered structure and a bonding pad formed on the interlayer insulating film. The multilayered structure includes a fluorine doped silicon oxide film layer and an SiH₄ based silicon oxide film layer. The SiH₄ based silicon oxide film layer is an upper layer relative to the fluorine doped silicon oxide film layer. Moreover, the SiH₄ based silicon oxide film layer and the fluorine doped silicon oxide film layer are in contact with each other in at least a part of a region right under the bonding pad.

Pile-up of fluorine in the region right under the bonding pad can be suppressed and an adhesion strength of the bonding pad can be enhanced. Consequently, a disconnection in the semiconductor device can be prevented, resulting in a contribution to an enhancement in a semiconductor device manufacturing yield and an operation reliability.

A second aspect of the present invention is directed to a semiconductor device including an interlayer insulating film having a multilayered structure and a bonding pad formed on the interlayer insulating film. The multilayered structure includes at least a fluorine doped silicon oxide film layer. The bonding pad is formed in a hole penetrating through the interlayer insulating film.

Even if pile-up of fluorine is generated in the interlayer insulating film, an adhesion strength of the bonding pad can be maintained. Consequently, a disconnection in the semiconductor device can be prevented, resulting in a contribution to an enhancement in a semiconductor device manufacturing yield and an operation reliability.

A third aspect of the present invention is directed to a method of manufacturing a semiconductor device including the following steps (a) and (b). The step (a) serves to form an interlayer insulating film having a multilayered structure including a fluorine doped silicon oxide film layer and an SiH₄ based silicon oxide film layer. The step (b) serves to form a bonding pad on the interlayer insulating film. Moreover, the step (a) includes the following steps (a1) to (a4). The step (a1) serves to form the fluorine doped silicon oxide film layer. The step (a2) serves to form another insulating film layer on the fluorine doped silicon oxide film layer. The step (a3) serves to flatten upper surfaces of the layers formed in the steps (a1) and (a2) and to expose the fluorine doped silicon oxide film layer to the upper surfaces partially or wholly. The step (a4) serves to form the SiH₄ based silicon oxide film layer after the step (a3). Furthermore, a region right under the bonding pad formed at the step (b) includes at least a part of a region in which the fluorine doped silicon oxide film layer is exposed at the step (a3).

Pile-up of fluorine in the region provided under the bonding pad can be prevented from being generated and an adhesion strength of the bonding pad can be enhanced. Consequently, a disconnection in the semiconductor device can be prevented, resulting in a contribution to an enhancement in a semiconductor device manufacturing yield and an operation reliability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor device according to a first embodiment,

FIGS. 2 to 4 are views for explaining a process for manufacturing the semiconductor device according to the first embodiment,

FIG. 5 is a sectional view showing a structure of a semiconductor device according to a second embodiment,

FIG. 6 is a sectional view showing a structure of a semiconductor device according to a third embodiment,

FIGS. 7 to 9 are views for explaining a process for manufacturing the semiconductor device according to the third embodiment,

FIG. 10 is a sectional view showing a structure of a semiconductor device according to a fourth embodiment,

FIG. 11 is a view for explaining a process for manufacturing the semiconductor device according to the fourth embodiment,

FIG. 12 is a sectional view showing a structure of a conventional semiconductor device,

FIGS. 13 to 15 are views for explaining a process for manufacturing the conventional semiconductor device, and

FIG. 16 is a view for explaining a problem in the conventional semiconductor device.

### DESCRIPTION OF THE PREFERRED EMBODIMENTS

<First Embodiment>

FIG. 1 is a sectional view showing a structure of a semiconductor device according to a first embodiment of the present invention. In FIG. 1, the same elements as those in FIG. 12 have the same reference numerals and their detailed description will be therefore omitted. The semiconductor device according to the present embodiment has such a structure that a dummy pattern 10 having an equal size to that of a bonding pad 6 is provided in a region right under the bonding pad 6 and an F doped silicon oxide film 4a and an SiH₄ based silicon oxide film 4c are in contact with each other in a region right above the dummy pattern 10 (that is, a region right under the bonding pad 6) as shown in FIG. 1. In other words, an interface of a TEOS based silicon oxide film 4b and the SiH₄ based silicon oxide film 4c is hardly present in the region right under the bonding pad 6.

In the F doped silicon oxide film 4a, a bond of Si and F is comparatively strong. Therefore, pile-up of fluorine is not caused in the interface of the F doped silicon oxide film 4a and the SiH₄ based silicon oxide film 4c. According to the semiconductor device of the present embodiment, consequently, the pile-up of the fluorine in the region right under the bonding pad 6 is suppressed so that an adhesion strength of the bonding pad 6 can be enhanced.

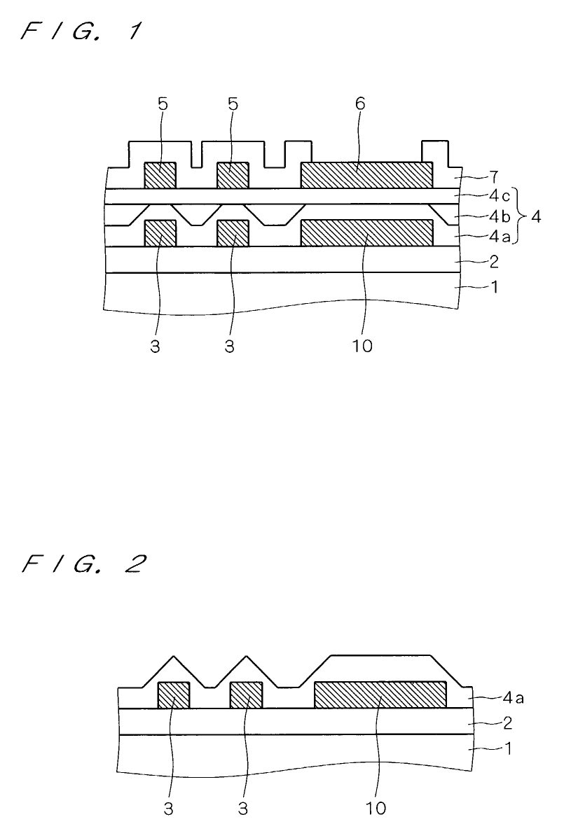

FIGS. 2 to 4 are views for explaining a process for manufacturing the semiconductor device according to the first embodiment illustrated in FIG. 1. The process for manufacturing the semiconductor device according to the present embodiment will be described below with reference to these drawings. First of all, a first interlayer insulating film 2 formed by a silicon oxide film containing no fluorine is provided on a silicon substrate 1, and an Al wiring material is deposited thereon and is patterned so that a first Al wiring 3 and a dummy pattern 10 are formed. Such a forming method is carried out by combining a CVD method, an etch back method, a CMP method and the like, for example. The dummy pattern 10 can be formed at the same step as the formation of the first Al wiring 3 by using the same material as that of the first Al wiring 3. Therefore, the number of steps is not increased as compared with a process for manufacturing a semiconductor device according to the conventional art.

The F doped silicon oxide film 4a is formed on the first interlayer insulating film 2, the first Al wiring 3 and the dummy pattern 10 to cover the first Al wiring 3 and the dummy pattern 10 (FIG. 2). The F doped silicon oxide film 4a is formed by a high density plasma CVD method adding a C₂F₆ gas to an SiH₄ gas and an O₂ gas as in the conventional art, for example. At this time, a thickness of the F doped silicon oxide film 4a is almost equal to that of the first Al wiring 3.

Next, the TEOS based silicon oxide film 4b is formed on the F doped silicon oxide film 4a by a plasma CVD method using TEOS and the O₂ gas as reaction gases (FIG. 3). Then, a flattening treatment is carried out over the F doped silicon oxide film 4a and the TEOS based silicon oxide film 4b by the CMP method. By the flattening treatment, the F doped silicon oxide film 4a provided on the dummy pattern 10 is scraped to be exposed sufficiently.

Subsequently, a heat treatment for improving quality of the F doped silicon oxide film 4a and the TEOS based silicon oxide film 4b is carried out at approximately 400° C. At this time, fluorine having a small bonding strength in the F doped silicon oxide film 4a is diffused into the TEOS based silicon oxide film 4b. In other words, the fluorine remaining on the F doped silicon oxide film 4a has a comparatively great bonding strength at this time.

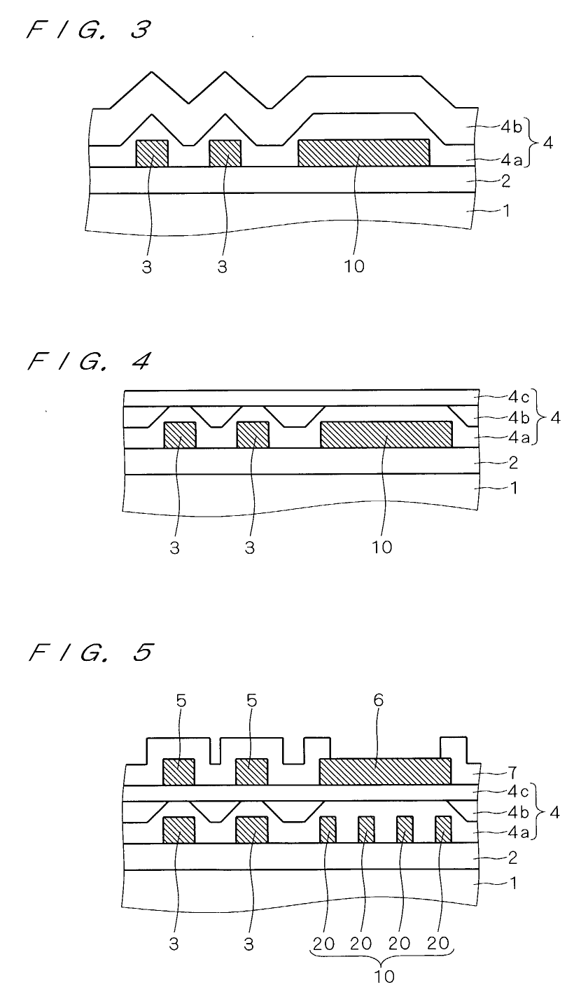

Thereafter, an SiH₄ based silicon oxide film 4c is formed on the F doped silicon oxide film 4a and the TEOS based silicon oxide film 4b which are flattened (FIG. 4). The SiH₄ based silicon oxide film 4c is formed by the plasma CVD method using SiH₄ and O₂ as reaction gases. As described above, the F doped silicon oxide film 4a in a region provided just above the dummy pattern 10 is exposed in the flattening treatment for the F doped silicon oxide film 4a and the TEOS based silicon oxide film 4b. In the exposed portion, therefore, the SiH₄ based silicon oxide film 4c is formed in contact with the F doped silicon oxide film 4a.

Next, a via hole for connecting the first Al wiring 3 to a second Al wiring 5 is formed on the second interlayer insulating film 4 by photolithography, dry etching and the like, which is not shown. By a combination of sputtering, the CVD method, the etch back method and the like, a tungsten plug is buried in the via hole to form a contact.

Then, an Al wiring material is deposited on the second interlayer insulating film 4 and is patterned so that the second Al wiring 5 and the bonding pad 6 are formed. The bonding pad 6 is formed in a region right above the dummy pattern 10. As a result, therefore, the F doped silicon oxide film 4a and the SiH₄ based silicon oxide film 4c are in contact with each other in a region right under the bonding pad 6. More specifically, an interface of the TEOS based silicon oxide film 4b and the SiH₄ based silicon oxide film 4c in which pile-up of fluorine is generated is hardly present in a region right under the bonding pad 6. On the other hand, Si and F are strongly bonded to each other in the F doped silicon oxide film 4a and the pile-up of the fluorine is not generated on the interface of the F doped silicon oxide film 4a and the SiH₄ based silicon oxide film 4c. Accordingly, the pile-up of the fluorine is not generated in the region right under the bonding pad 6.

Thereafter, a silicon nitride film to be a passivation film 7 is formed by the plasma CVD method, for example, and an upper part of the bonding pad 6 is opened so that the semiconductor device shown in FIG. 1 is formed.

As described above, according to the semiconductor device of the present embodiment, the F doped silicon oxide film 4a and the SiH₄ based silicon oxide film 4c in the second interlayer insulating film 4 are in contact with each other in the region right under the bonding pad 6. Accordingly, the interface of the TEOS based silicon oxide film 4b and the SiH₄ based silicon oxide film 4c is hardly present in the region right under the bonding pad 6. Therefore, the pile-up of the fluorine in the region right under the bonding pad 6 is suppressed so that an adhesion strength of the bonding pad 6 can be enhanced. Consequently, a disconnection in the semiconductor device can be prevented, resulting in a contribution to an enhancement in a semiconductor device manufacturing yield and an operation reliability.

The fluorine may be added to the TEOS based silicon oxide film 4b and the SiH₄ based silicon oxide film 4c in the formation to further reduce a dielectric constant. If the fluorine is added in the formation of the oxide film by the plasma CVD method as described above, however, etching of the oxide film is simultaneously caused by the fluorine so that a film forming speed is decreased. Accordingly, in the case in which importance is attached to a manufacturing efficiency and a manufacturing cost, it is desirable that the TEOS based silicon oxide film 4b and the SiH₄ based silicon oxide film 4c should be formed without an addition of the fluorine as in the present embodiment.

<Second Embodiment>

In the first embodiment, the dummy pattern 10 is formed in a single aluminum pattern having an equal size to that of the bonding pad 6. Aluminum is softer and deformed more easily than a silicon oxide film. Therefore, the second interlayer insulating film 4 interposed between the dummy pattern 10 formed of aluminum and the bonding pad 6 is fragile to an impact applied from the outside and a crack might be generated by a shock in a probe needle touch with the bonding pad 6 at time of execution of a probe test or lead wire hitting on the bonding pad 6.

FIG. 5 is a sectional view showing a structure of a semiconductor device according to a second embodiment. In FIG. 5, the same elements as those in FIG. 1 have the same reference numerals. As shown in FIG. 5, in the semiconductor device according to the present embodiment, a dummy pattern 10 is constituted by a plurality of patterns 20 provided at a predetermined interval. For convenience of explanation in this specification, each pattern 20 to be an element of the dummy pattern 10 is defined as “an element dummy pattern 20”.

Thus, the dummy pattern 10 to be provided in a region under a bonding pad 6 is constituted by the element dummy patterns 20 so that the shock applied from the outside is caused to escape into a second interlayer insulating film 4 provided in a gap between the element dummy patterns 20. Consequently, the element dummy pattern 20 is deformed with difficulty. Accordingly, a crack can be prevented from being generated on the second interlayer insulating film 4 by the shock applied from the outside, resulting in a contribution to an enhancement in a semiconductor device manufacturing yield and an operation reliability.

Since a structure of the semiconductor device according to the present embodiment and a method of manufacturing the structure are the same as those in the first embodiment except that the dummy pattern 10 is formed by a plurality of element dummy patterns 20, moreover, detailed description will be omitted. Also in the present embodiment, furthermore, it is apparent that the effect of enhancing an adhesion strength of the bonding pad 6 can be obtained in the same manner as in the first embodiment.

As a shape of the element dummy pattern 20, a square pattern and a line pattern can be employed to easily give an arrangement in respect of a design. Moreover, it is desirable that a size of the element dummy pattern 20 should be equal to or smaller than 1/10 of a length of one side of the bonding pad 6 (for example, if the dummy pattern 10 is a regular square pattern having a side of 100 μm, each of the element dummy patterns 20 is a square pattern having a side of 10 μm or less).

<Third Embodiment>

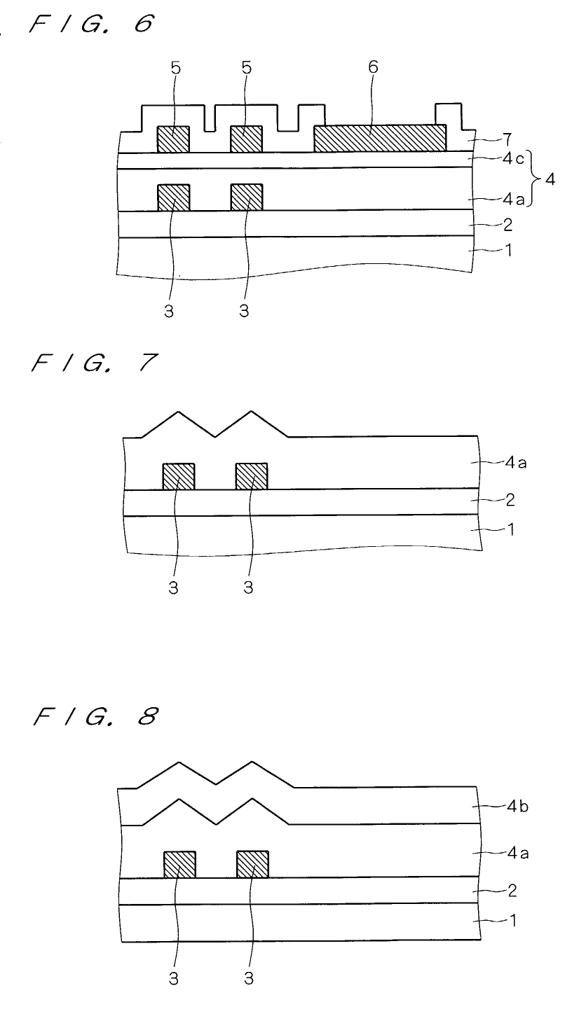

FIG. 6 is a sectional view showing a structure of a semiconductor device according to a third embodiment of the present invention. Also in FIG. 6, the same elements as those in FIG. 1 have the same reference numerals and detailed description will be thereby omitted. In the semiconductor device according to the present embodiment, a second interlayer insulating film 4 provided under a bonding pad 6 has a two-layered structure including an F doped silicon oxide film 4a and an SiH₄ based silicon oxide film 4c as shown in FIG. 6. In other words, the SiH₄ based silicon oxide film 4c is formed on the F doped silicon oxide film 4a. Accordingly, an interface of a TEOS based silicon oxide film 4b and the SiH₄ based silicon oxide film 4c is not present in the second interlayer insulating film 4 provided under the bonding pad 6.

According to the semiconductor device of the present embodiment, therefore, pile-up of fluorine is not generated in the second interlayer insulating film 4 provided under the bonding pad 6. As a result, an adhesion strength of the bonding pad 6 can be enhanced.

FIGS. 7 to 9 are views for explaining a process for manufacturing the semiconductor device according to the third embodiment illustrated in FIG. 6. With reference to these drawings, description will be given to the process for manufacturing the semiconductor device according to the present embodiment. First of all, a first interlayer insulating film 2 is formed on a silicon substrate 1 and a first Al wiring 3 is formed thereon.

Then, the F doped silicon oxide film 4a is formed on the first interlayer insulating film 2 and the first Al wiring 3 by a high density plasma CVD method adding a C₂F₆ gas to an SiH₄ gas and an O₂ gas, for example, in order to cover the first Al wiring 3. At this time, a thickness of the F doped silicon oxide film 4a is set to be a double of a thickness of the first Al wiring 3 or more, or the thickness of the first Al wiring 3+300 nm or more (FIG. 7).

Next, the TEOS based silicon oxide film 4b is formed on the F doped silicon oxide film 4a by a plasma CVD method using TEOS and the O₂ gas as reaction gases (FIG. 8). Subsequently, a flattening treatment is carried out over the F doped silicon oxide film 4a and the TEOS based silicon oxide film 4b by a CMP method. At this time, the TEOS based silicon oxide film 4b is completely scraped by the flattening treatment such that the F doped silicon oxide film 4a is exposed to a whole upper surface.

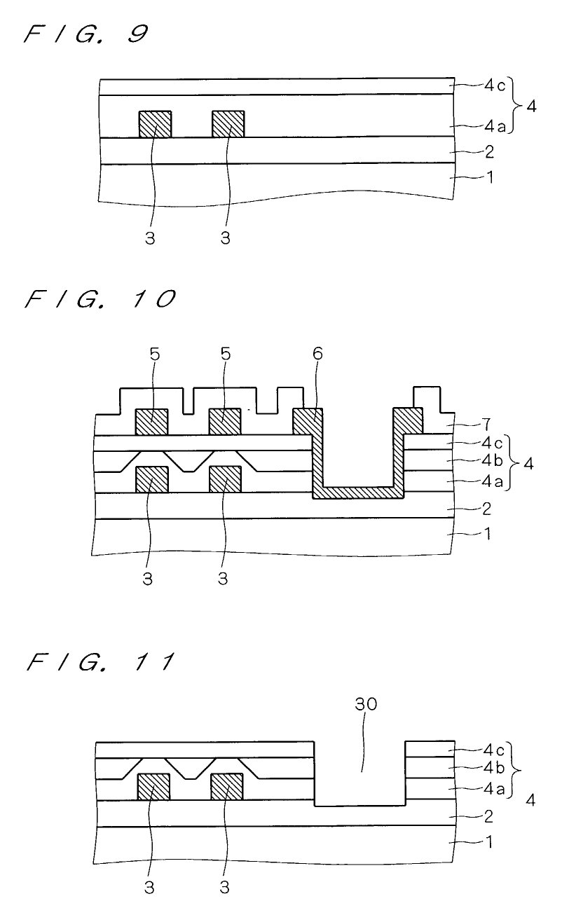

Thereafter, the SiH₄ based silicon oxide film 4c is formed on the F doped silicon oxide film 4a thus flattened (FIG. 9). The SiH₄ based silicon oxide film 4c is formed by the plasma CVD method by using SiH₄ and O₂ as reaction gases. As described above, the TEOS based silicon oxide film 4b is completely scraped and the F doped silicon oxide film 4a is exposed in the flattening treatment for the F doped silicon oxide film 4a and the TEOS based silicon oxide film 4b. As a result, therefore, the second interlayer insulating film 4 has the two-layered structure including the F doped silicon oxide film 4a and the SiH₄ based silicon oxide film 4c.

Next, a via hole for connecting the first Al wiring 3 to a second Al wiring 5 is formed on the second interlayer insulating film 4 and a tungsten plug is buried in the via hole to form a contact, which is not shown.

Then, the second Al wiring 5 and the bonding pad 6 are formed on the second interlayer insulating film 4. The second interlayer insulating film 4 has the two-layered structure including the F doped silicon oxide film 4a and the SiH₄ based silicon oxide film 4c. Therefore, an interface of the TEOS based silicon oxide film 4b and the SiH₄ based silicon oxide film 4c is not present under the bonding pad 6.

Thereafter, a silicon nitride film to be a passivation film 7 is formed by the plasma CVD method, for example, and an upper part of the bonding pad 6 is opened so that the semiconductor device shown in FIG. 6 is formed.

As described above, according to the semiconductor device of the present embodiment, the interface of the TEOS based silicon oxide film 4b and the SiH₄ based silicon oxide film 4c is not present on the second interlayer insulating film 4 provided under the bonding pad 6. Therefore, pile-up of fluorine is not generated in the second interlayer insulating film 4. As a result, an adhesion strength of the bonding pad 6 can be enhanced. Consequently, a disconnection in the semiconductor device can be prevented, resulting in a contribution to an enhancement in a semiconductor device manufacturing yield and an operation reliability.

In the present embodiment, the TEOS based silicon oxide film 4b which is once formed is wholly scraped. Accordingly, even if the F doped silicon oxide film 4a is formed very thickly and is flattened without the formation of the TEOS based silicon oxide film 4b thereon, a semiconductor device having the same structure as that in FIG. 6 can be consequently formed. As described above, however, the F doped silicon oxide film 4a is formed at a lower speed and takes a higher formation cost than the TEOS based silicon oxide film 4b. In consideration of a manufacturing efficiency and a manufacturing cost, therefore, it is desirable that the TEOS based silicon oxide film 4b should be once formed in the flattening treatment for the SiH₄ based silicon oxide film 4c as in the present embodiment.

<Fourth Embodiment>

FIG. 10 is a sectional view showing a structure of a semiconductor device according to a fourth embodiment of the present invention. Also in FIG. 10, the same elements as those in FIG. 1 have the same reference numerals and detailed description will be therefore omitted. In the semiconductor device according to the present embodiment, a bonding pad 6 is formed in a hole penetrating through a second interlayer insulating film 4 as shown in FIG. 10. More specifically, a bottom surface of the bonding pad 6 reaches a first interlayer insulating film 2 provided under the second interlayer insulating film 4.

Accordingly, even if pile-up of fluorine is generated on an interface of a TEOS based silicon oxide film 4b and an SiH₄ based silicon oxide film 4c in the second interlayer insulating film 4, for example, an adhesion strength in the bottom surface of the bonding pad 6 is not influenced. Moreover, since the first interlayer insulating film 2 has a single layer structure comprising a silicon oxide film containing no fluorine, the pile-up of the fluorine is not generated. Consequently, the adhesion strength of the bonding pad 6 can be prevented from being reduced.

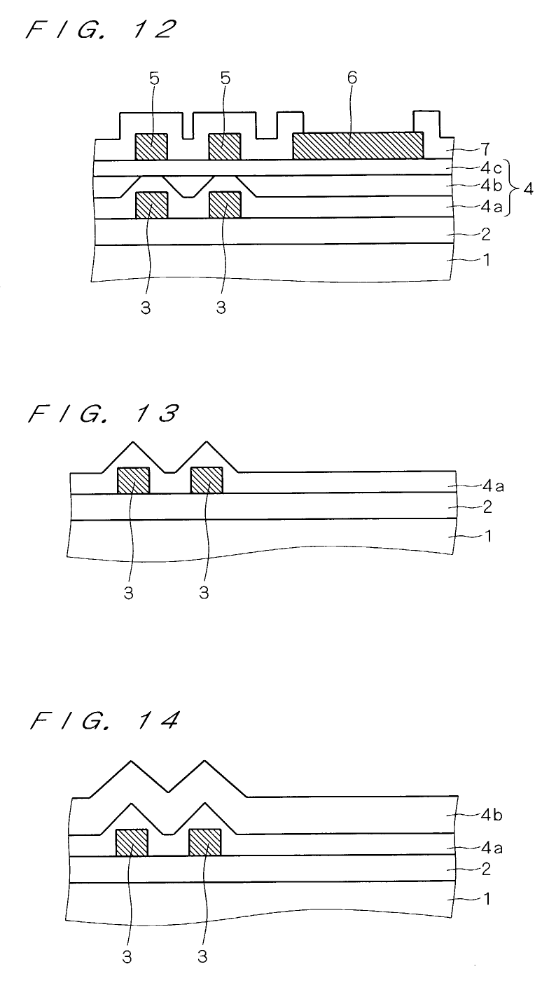

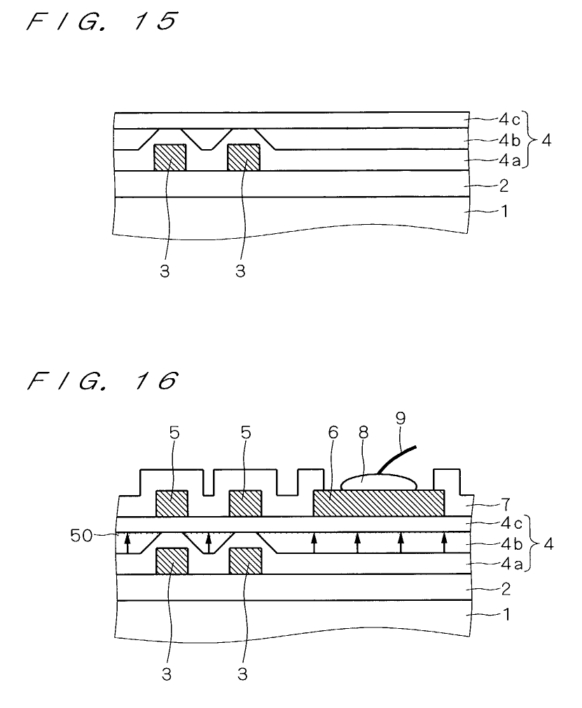

FIG. 11 is a view for explaining a process for manufacturing the semiconductor device according to the fourth embodiment shown in FIG. 10. With reference to FIG. 11, description will be given to the process for manufacturing the semiconductor device according to the present embodiment. First of all, the first interlayer insulating film 2 and a first Al wiring 3 are formed on a silicon substrate 1 and the second interlayer insulating film 4 having an F doped silicon oxide film 4a, the TEOS based silicon oxide film 4b and the SiH₄ based silicon oxide film 4c is formed thereon at the same steps (FIGS. 13 to 15) as those in the method of manufacturing the conventional semiconductor device. Then, a via hole for connecting the first Al wiring 3 to a second Al wiring 5 is formed on the second interlayer insulating film 4 and a tungsten plug is buried in the via hole to form a contact.

Then, a hole 30 in which the bonding pad 6 is to be formed is provided by using photolithography or dry etching (FIG. 11). Thereafter, an Al wiring material is deposited on the second interlayer insulating film 4 and in the hole 30 and is patterned, and the second Al wiring 5 is formed on the second interlayer insulating film 4 and the bonding pad 6 is formed in the hole 30. As a result, the bottom surface of the bonding pad 6 reaches the first interlayer insulating film 2.

Subsequently, a silicon nitride film to be a passivation film 7 is formed by a plasma CVD method, for example, and an upper part of the bonding pad 6 is opened so that the semiconductor device shown in FIG. 10 is formed.

As described above, according to the semiconductor device of the present embodiment, even if pile-up of fluorine is generated on the interface of the TEOS based silicon oxide film 4b and the SiH₄ based silicon oxide film 4c in the second interlayer insulating film 4, an adhesion strength in the bottom surface of the bonding pad 6 is not influenced so that the adhesion strength can be prevented from being reduced by the pile-up. Moreover, since the first interlayer insulating film 2 has the single layer structure comprising a silicon oxide film containing no fluorine, the pile-up of the fluorine is not generated. Consequently, a disconnection in the semiconductor device can be prevented, resulting in a contribution to an enhancement in a semiconductor device manufacturing yield and an operation reliability.

In the present embodiment, moreover, even if the second interlayer insulating film 4 including the F doped silicon oxide film 4a does not have the SiH₄ based silicon oxide film 4c formed on an upper surface, it is possible to obtain the effect of enhancing the adhesion strength of the bonding pad 6. As described above, the SiH₄ based silicon oxide film 4c has the function of enhancing the adhesion strength of the bonding pad 6 when forming the bonding pad 6 on the second interlayer insulating film 4 including the F doped silicon oxide film 4a. In the present embodiment, however, it is apparent that the adhesion strength in the bottom surface of the bonding pad 6 can be enhanced irrespective of a layer structure of the second interlayer insulating film 4. Accordingly, even if the second interlayer insulating film 4 does not have the SiH₄ based silicon oxide film 4c to allow a compound of a barrier metal on a surface of the bonding pad 6 and fluorine to be formed on an interface of the second interlayer insulating film 4 and the bonding pad 6, the adhesion strength of the bonding pad 6 can be prevented from being deteriorated.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an interlayer insulating film having a multilayered structure including a fluorine doped silicon oxide film layer and an SiH₄ based silicon oxide film layer; and
a bonding pad formed on said interlayer insulating film,
wherein said SiH₄ based silicon oxide film layer is an upper layer relative to said fluorine doped silicon oxide film layer in said multilayered structure, and
said SiH₄ based silicon oxide film layer and said fluorine doped silicon oxide film layer are in contact with each other in at least a part of a region right under said bonding pad.

2. The semiconductor device according to claim 1, wherein a dummy pattern is provided in a region right under said bonding pad and below said fluorine doped silicon oxide film layer, and
another insulating film layer is provided between said fluorine doped silicon oxide film layer and said SiH₄ based silicon oxide film layer in at least a partial region other than a region right above said dummy pattern.

3. The semiconductor device according to claim 2, wherein said dummy pattern includes a plurality of element dummy patterns.

4. The semiconductor device according to claim 1, wherein said multilayered structure is a three-layered structure having a TEOS based silicon oxide film layer between said SiH₄ based silicon oxide film layer and said fluorine doped silicon oxide film layer.

5. The semiconductor device according to claim 1, wherein said SiH₄ based silicon oxide film layer is provided on said fluorine doped silicon oxide film layer in said multilayered structure of said interlayer insulating film.

6. The semiconductor device according to claim 5, wherein said interlayer insulating film has a two-layered structure including said SiH₄ based silicon oxide film layer and said fluorine doped silicon oxide film layer.

7. The semiconductor device according to claim 4, wherein said TEOS based silicon oxide film layer is formed without an addition of fluorine.

8. The semiconductor device according to claim 1, wherein said SiH₄ based silicon oxide film layer is formed without an addition of fluorine.

9. A semiconductor device comprising:
an interlayer insulating film including at least a fluorine doped silicon oxide film layer; and
a bonding pad,
wherein said bonding pad is formed in a hole penetrating through said interlayer insulating film.

10. The semiconductor device according to claim 9, wherein said interlayer insulating film has a three-layered structure including a TEOS based silicon oxide film layer provided on said fluorine doped silicon oxide film layer and an SiH₄ based silicon oxide film layer provided on said TEOS based silicon oxide film layer.

11. The semiconductor device according to claim 10, wherein said TEOS based silicon oxide film layer is formed without an addition of fluorine.

12. The semiconductor device according to claim 9, wherein said SiH₄ based silicon oxide film layer is formed without an addition of fluorine.

13. A method of manufacturing a semiconductor device comprising the steps of:
(a) forming an interlayer insulating film having a multilayered structure including a fluorine doped silicon oxide film layer and an SiH₄ based silicon oxide film layer; and
(b) forming a bonding pad on said interlayer insulating film, said step (a) including:
(a1) forming said fluorine doped silicon oxide film layer;
(a2) forming another insulating film layer on said fluorine doped silicon oxide film layer;
(a3) flattening upper surfaces of said layers formed in said steps (a1) and (a2) and exposing said fluorine doped silicon oxide film layer to said upper surfaces partially or wholly; and
(a4) forming said SiH₄ based silicon oxide film layer after said step (a3),
wherein a region right under said bonding pad formed at said step (b) includes at least a part of a region in which said fluorine doped silicon oxide film layer is exposed at said step (a3).

14. The method of manufacturing a semiconductor device according to claim 13, further comprising the step of:
(c) forming a dummy pattern prior to said step (a) in said region right under said bonding pad which is formed at said step (b).
